(19) United States
(12) Patent Application Publication
(10) Pub. No.: US 2022/0204671 A1
(43) Pub. Date: Jun. 30, 2022

(54) FLUORINATED ACRYLATE-BASED COPOLYMER AND PHOTOSENSITIVE RESIN COMPOSITION COMPRISING SAME

(71) Applicant: ROHM AND HAAS ELECTRONIC MATERIALS KOREA LTD., Chungcheongnam-do (KR)

(72) Inventors: Kyung-Jae Park, Gyeonggi-do (KR); Seung-Keun Kim, Gyeonggi-do (KR); Kyu-Cheol Lee, Gyeonggi-do (KR)

(21) Appl. No.: 17/543,563

(22) Filed: Dec. 6, 2021

(30) Foreign Application Priority Data
Dec. 24, 2020 (KR) 10-2020-0182741

(51) Int. Cl. C08F 220/24; C08F 265/06

(52) U.S. Cl. CPC C08F 220/24; C08F 265/06

(57) ABSTRACT

The present invention relates to a fluorinated acrylate-based copolymer and to a photosensitive resin composition comprising the same. The copolymer can have excellent water repellency even with a relatively low content of fluorine by introducing a non-polar ring-containing unit, so that it can prevent coating imbalance and decreases in the pattern strength that may occur when the fluorine content is high.

### TECHNICAL FIELD

The present invention relates to a fluorinated acrylate-based copolymer and to a photosensitive resin composition comprising the same. More specifically, the present invention relates to a fluorinated acrylate-based copolymer that is applied to top coating barrier ribs for inkjet and is excellent in water repellency, pattern formation, and strength, and to a photosensitive resin composition comprising the same.

### BACKGROUND ART

A photoresist is a photosensitive resin composition used for selectively processing a semiconductor device. In a process for manufacturing semiconductor devices, a photoresist is coated on a substrate, exposed to a source of activating radiation through a photomask, and then developed to obtain a pattern. In recent years, immersion lithography is being used to achieve minimum feature widths on a nanometer scale. In order to prevent the photoresist component from leaching out into the immersion liquid, a top coating is formed on the photoresist layer to serve as a barrier between the immersion liquid and the photoresist layer.

Korean Patent No. 688569 discloses a top coating composition containing fluorine and a method of forming a photoresist pattern using the same. The composition according to the above patent is composed of a copolymer comprising a unit derived from an acrylate having a fluorine-substituted hydrocarbon group having 1 to 6 carbon atoms, maleic anhydride, and an olefin monomer and having a weight average molecular weight of 5,000 to 100,000; and an organic solvent.

Meanwhile, in order to replace the photolithography method mainly used in the process for manufacturing display devices, various new processes have been recently adopted. The inkjet method is a representative one. In the inkjet method, a top coating is formed on a substrate and subjected to exposure and development processes to form barrier ribs, and ink is then injected between the barrier ribs. Since the inkjet method can reduce the materials required for the process and simplify the process, it is applied to a liquid crystal display (LCD), an organic light emitting display (OLED), a quantum dot display (QLED), and the like.

### Prior Art Document (Patent Document 1) Korean Patent No, 688569

### DISCLOSURE OF INVENTION

### Technical Problem

In order for the inkjet method to be workable, the pattern shape, surface uniformity, and strength of the barrier ribs must be excellent so that the ink can be stably contained between the barrier ribs, and the water repellency of the barrier ribs must be secured so that the ink injected between the barrier ribs does not leach out. However, the conventional fluorine-based resin composition for top coating used in this method lacks economic feasibility due to a high content of fluorine or has difficulties in manufacturing or problems in the curing quality.

As a result of research conducted by the present inventors, it has been discovered that it is possible to maintain a low surface tension even if the fluorine content is reduced by introducing a non-polar ring-containing unit into the fluorine-based binder and to enhance the pattern formation, surface uniformity, and strength by blending it with other photopolymerizable compounds.

Accordingly, an object of the present invention is to provide a copolymer having a low content of fluorine as compared with the prior art and improved water repellency and a photosensitive resin composition comprising the same and having appropriate pattern formation, surface uniformity, and strength for manufacturing top coating barrier ribs for inkjet.

### Solution to Problem

In order to achieve the above object, the present invention provides a fluorinated acrylate-based copolymer comprising (b1) a structural unit represented by the following Formula 1a or 1b, (b2) a structural unit represented by the following Formula 2, (b3) a structural unit represented by the following Formula 3, and (b4) a structural unit derived from an ethylenically unsaturated carboxylic acid:

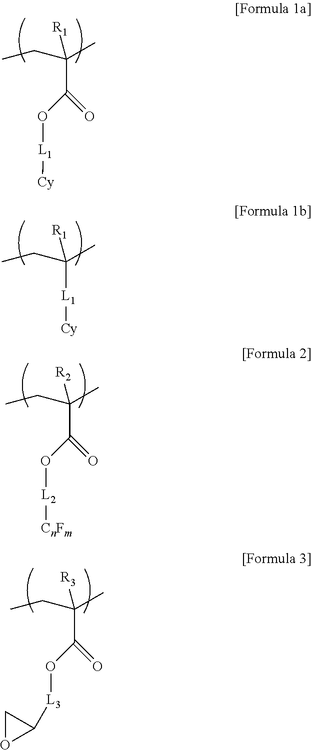

In the above formulae, R₁, R₂, and R₃ are each independently hydrogen or alkyl having 1 to 6 carbon atoms; L₁, L₂, and L₃ are each independently a single bond or a. chain having 1 to 10 carbon atoms with or without one or more heteroatoms selected from N, S, and O, Cy is an aromatic or non-aromatic hydrocarbon ring having 4 to 13 carbon atoms with or without one or more substituents; and CₙFₘ is fluoroalkyl having n carbon atoms and m fluorine atoms, wherein n is an integer of 1 to 10, m is an integer of 1 or more, and 2n−2≤m≤2n+1.

In addition, the present invention provides a photosensitive resin composition, which comprises an alkali-soluble resin, a photopolvmerizable compound, and a photopolymerization initiator, wherein the alkali-soluble resin comprises a copolymer comprising (b1) a structural unit represented by the above Formula 1a or 1b, (b2) a structural unit represented by the above Formula 2, (b3) a structural unit represented by the above Formula 3, and (b4) a structural unit derived from an ethylenically unsaturated carboxylic acid.

### ADVANTAGEOUS EFFECTS OF INVENTION

The fluorinated acrylate-based copolymer according to the present invention has excellent water repellency even with a relatively low content of fluorine by introducing a non-polar ring-containing unit, thereby lowering the production cost as compared with the prior art. In addition, the fluorinated acrylate-based copolymer may prevent coating imbalance and decreases in the pattern strength that may occur when the fluorine content is high.

Accordingly, the photosensitive resin composition comprising the fluorinated acrylate-based copolymer has excellent water repellency, so that it is possible to prevent the ink liquid from leaching out when it is used for the barrier ribs of a top coating for inkjet. In addition, the photosensitive resin composition can be expected to form a stable pattern while the film aggregation phenomenon is suppressed after coating.

### BRIEF DESCRIPTION OF DRAWINGS

FIG. 1 shows images of the compositions of Comparative Example 1 and Examples 1 to 6 after development.

FIG. 2 shows images of the compositions of Comparative Example 1 and Examples 1 to 6 after post-bake.

FIG. 3 shows images of the coating surface of the compositions of Comparative Example 1 and Examples 1 to 6.

### BEST MODE FOR CARRYING OUT THE INVENTION

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. In addition, all numbers and expressions relating to quantities of components, reaction conditions, and the like used herein are to be understood as being modified by the term “about” unless specifically stated otherwise.

As used herein, the term “(meth)acryl” refers to “acryl” and/or “methacryl,” and the term “(meth)acrylate” refers to “acrylate” and/or “methacrylate.”

In the present specification, molecular weight or weight average molecular weight does not usually accompany a unit, but it may be understood to have a unit of g/mole or Da.

### Fluorinated Acrylate-Based Copolymer

The fluorinated acrylate-based copolymer according to the present invention has excellent water repellency even with a relatively low content of fluorine by introducing a non-polar ring-containing unit, thereby lowering the production cost as compared with the prior art. In addition, the fluorinated acrylate-based copolymer may prevent coating imbalance and decreases in the pattern strength that may occur When the fluorine content is high.

The fluorinated acrylate-based copolymer according to the present invention comprises (b1) a structural unit represented by the following Formula 1a or 1b, (b2) a structural unit represented by the following Formula 2, (b3) a structural unit represented by the following Formula 3, and (b4) a structural unit derived from an ethylenically unsaturated carboxylic acid:

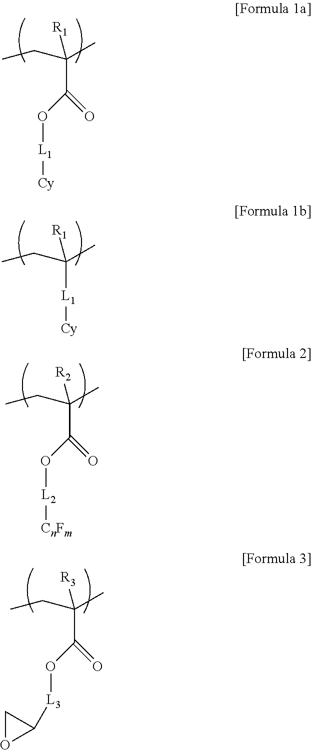

In the above formulae, R₁, R₂, and R₃ are each independently hydrogen or alkyl having 1 to 6 carbon atoms; L₁, L₂, and L₃ are each independently a single bond or a. chain having 1 to 10 carbon atoms with or without one or more heteroatoms selected from N, S, and Cy is an aromatic or non-aromatic hydrocarbon ring having 4 to 13 carbon atoms with or without one or more substituents; and CₙFₘ is fluoroalkyl having n carbon atoms and m fluorine atoms, wherein n is an integer of 1 to 10, m is an integer of 1 or more, and 2n−2≤m≤2n+1.

In Formulae 1a to 3, R₁, R₂, and R₃ are each independently hydrogen or alkyl having 1 to 6 carbon atoms and, specifically, may be hydrogen or alkyl having 1 to 3 carbon atoms.

In Formulae 1a to 3, L₁, L₂, and L₃ are each independently a single bond or a chain having 1 to 10 carbon atoms with or without one or more heteroatoms selected from N, S, and O and, specifically, may be a single bond or a chain having 1 to 10 carbon atoms with or without one or more O in the chain e.g., alkylene, oxyalkylene, alkylene glycol, etc.). The number of carbon atoms in the chain may be 1 to 10, 1 to 6, 1 to 3, 3 to 10, or 6 to 10.

In Formulae 1a and 1b, Cy is an aromatic or non-aromatic hydrocarbon ring having 4 to 13 carbon atoms, each having one or more substituents or not. Since the hydrocarbon ring does not contain a heteroatom and thus has non-polarity, the water repellency of the copolymer can be enhanced.

The aromatic hydrocarbon ring may be, for example, an aromatic hydrocarbon ring having 6 to 13 carbon atoms, that is, an aryl having 6 to 13 carbon atoms, The number of carbon atoms constituting the aromatic hydrocarbon ring may be specifically 6 to 13 or 6 to 10. The aromatic hydrocarbon ring may be a single ring or multiple rings and, specifically, may be phenyl, naphthalenyl, or the like.

The non-aromatic hydrocarbon ring may be, for example, an alicyclic group such as cycloalkyl and cycloalkenyl having 4 to 13 carbon atoms, The number of carbon atoms constituting the non-aromatic hydrocarbon ring may be specifically 4 to 13 or 4 to 8. The non-aromatic hydrocarbon ring may be a single ring or multiple rings and, specifically, may be cyclopentyl, cyclohexyl, dicyclopentanyl, dicyclopentenyl, or the like.

As a specific example, in Formulae 1a and 1b, Cy may be selected from the group consisting of phenyl, cyclohexyl, and dicyclopentanyl, each having one or more substituents or not.

The aromatic or non-aromatic hydrocarbon ring may have one or more substituents, for example, 1 to 3 substituents. The substituent may be, for example, one or more selected from the group consisting of halogen, hydroxyl, acetyl, vinyl, C₁₋₁₂ alkyl, C₁₋₁₂ alkoxy, and C₁₋₆ alkoxy C₁₋₆ alkyl. Particular examples of the substituent may include chloro, bromo, iodo, hydroxyl, acetyl, vinyl, methyl, ethyl, propyl, butyl, hexyl, heptyl, octyl, nonyl, methoxy, ethoxy, propoxy, and the like.

In Formula 2, CₙFₘ is fluoroalkyl having n carbon atoms and m fluorine atoms, wherein n is an integer of 1 to 10, in is an integer of 1 or more, and 2n−2≤m≤2n+1, Since it contains fluorine, it can enhance the water repellency of the copolymer. The number of carbon atoms in the fluoroalkyl. may be 1 to 10, for example, 1 to 8, 1 to 6, 1 to 3, 3 to 10, or 6 to 10, In addition, the fluoroalkyl may be a straight or branched chain.

The structural unit (b1) may comprise one or two or more structural units represented by Formula 1a or 1b as exemplified above.

The structural unit (b1) may be derived from an ethylenically unsaturated compound containing an aromatic or non-aromatic hydrocarbon ring.

Particular examples of the ethylenically unsaturated compound containing an aromatic hydrocarbon ring may include phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, chlorostyrene, bromostyrene, iodostyrene, methoxystyrene, ethoxystyrene, propoxystyrene, p-hydroxy-α-methylstyrene, acetylstyrene, vinyltoluene, divinylbenzene, vinylphenol, o-vinylbenzyl Methyl ether, m-vinylbenzyl methyl ether, and p-vinylbenzyl methyl ether.

Particular examples of the ethylenically unsaturated compound containing a non-aromatic hydrocarbon ring may include cyclopentyl (meth)acrylate, cyclohexyl (meth)acrylate, 2-methylcyclohexyl (meth)acrylate, dicyclopentanyl (meth)acrylate, dicyclopentenyl (meth)acrylate, 2-dicyclopentanyloxyethyl (meth)acrylate, dicyclopentenyloxyethyl (meth)acrylate, and isobornyl (meth)acrylate.

The content of the structural unit (b1) may be 10 to 40% by mole based on 100% by mole of the structural units constituting the fluorinated acrylate-based copolymer. Specifically, the content of the structural unit (b1) may be 10 to 30% by mole, 10 to 20% by mole, 15 to 40% by mole, 20 to 40% by mole, or 15 to 35% by mole, based on 100% by mole of the structural units constituting the fluorinated acrylate-based copolymer.

The structural unit (b2) may comprise one or two or more structural units represented by Formula 2 as exemplified above.

As an example, the structural unit (b2) may comprise a structural unit in which is 2n 1 and a structural unit in which m is 2n+1, The molar ratio between them may be 1:5 to 5:1, for example, 1:4 to 4:1, 1:3 to 31, 1:2 to 2:1, 1:1 to 1:4, 1:1 to 4:1, 1:1 to 3:1, 1:1 to 1:3, 1:1 to 1:2, or 1:1 to 2:1.

The structural unit (b2) may be derived from an ethylenically unsaturated compound containing a fluoroalkyl group.

Particular examples of the ethylenically unsaturated compound containing a fluoroalkyl group may include trifluoromethyl (meth)acrylate, trifluoroethyl (meth)acrylate, tetrafluoroethyl (meth)acrylate, tetrafluoropropyl (meth)acrylate, perfluoroethyl (meth)acrylate, pentafluoropropyl (meth)acrylate, hexafluoropropyl (meth)acrylate, perfluoropropyl (meth)acrylate, heptafluorobutyl (meth)acrylate, octafluorobutyl (meth)acrylate, perfluorobutyl (meth)acrylate, octafluoropentyl (meth)acrylate, nonafluoropentyl (meth)acrylate, decafluoropentyl (meth)acrylate, perfluoropentyl (meth)acrylate, perfluorohexyl (meth)acrylate, perfluoroheptyl (meth)acrylate, perfluorooctyl (meth)acrylate, perfluorononyl (meth)acrylate, and perfluorodecyl (meth)acrylate.

The content of the structural unit (b2) may be 10 to 50% by mole based on 100% by mole of the structural units constituting the fluorinated acrylate-based copolymer. Specifically, the content of the structural unit (b2) may be 10 to 45% by mole, 10 to 40% by mole, 10 to 35% by mole, 10 to 30% by mole, or 10 to 20% by mole, based on 100% by mole of the structural units constituting the fluorinated acrylate-based copolymer.

The structural unit (b3) may comprise one or two or more structural units represented by Formula 3 as exemplified above.

The structural unit (b3) may be derived from an ethylenically unsaturated compound containing an epoxy group.

Particular examples of the ethylenically unsaturated compound containing an epoxy group may include glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, and 4-hydroxybutyl (meth)acrylate glycidyl ether.

The content of the structural unit (b3) may be 10 to 40% by mole based on 100% by mole of the structural units constituting the fluorinated acrylate-based copolymer. Specifically, the content of the structural unit (b3) may be 10 to 35% by mole, 10 to 30% by mole, 15 to 40% by mole, 20 to 40% by mole, or 15 to 35% by mole, based on 100% by mole of the structural units constituting the fluorinated acrylate-based copolymer.

The structural unit (b4) may comprise one or two or more structural units derived from an ethylenically unsaturated carboxylic acid.

The ethylenically unsaturated carboxylic acid is a polymerizable unsaturated monomer having one or more carboxyl groups in the molecule. Particular examples thereof may include an unsaturated monocarboxylic acid such as (meth)acrylic acid, crotonic acid, α-chloroacrylic acid, and cinnamic acid; an unsaturated dicarboxylic acid such as maleic acid, fumaric acid, itaconic acid, citraconic acid, and mesaconic acid; and an unsaturated polycarboxylic acid of trivalence or more. The structural unit derived from the above-exemplified compounds may be contained in the copolymer alone or in combination of two or more.

The content of the structural unit (b4) may be 5 to 30% by mole based on 100% by mole of the structural units constituting the fluorinated acrylate-based copolymer. Specifically, the content of the structural unit (b4) may be 5 to 25% by mole, 5 to 20% by mole, 10 to 30% by mole, 10 to 25% by mole, or 10 to 20% by mole, based on 100% by mole of the structural units constituting the fluorinated acrylate-based copolymer.

The fluorinated acrylate-based copolymer may be a random copolymer comprising the structural units (b1) to (b4).

According to an embodiment, examples of the copolymer having structural units (b1) to (b4) may include a copolymer of styrene/trifluoroethyl (meth)acrylate/perfluorohexyl (meth)acrylate/glycidyl (meth)acrylate/(meth)acrylic acid, a copolymer of dicyclopentanyl (meth)acrylate/trifluoroethyl (meth)acrylate/perfluorohexyl (meth)acrylate/glycidyl (meth)acrylate/(meth)acrylic acid, and a copolymer of cyclohexyl (meth)acrylate/trifluoroethyl (meth)acrylate/perfluorohexyl (meth)acrylate/glycidyl (meth)acrylate/(meth)acrylic acid. One, two, or more of the copolymers may be contained in the photosensitive resin composition.

In addition, the fluorinated acrylate-based copolymer may further comprise a structural unit (b5) derived from an ethylenically unsaturated compound different from the structural units (b1) to (b4). For example, the ethylenically unsaturated compound may comprise at least one ethylenically unsaturated carboxylic acid ester-based compound.

Particular examples of the ethylenically unsaturated carboxylic acid ester-based compound may include methyl (meth)acrylate, ethyl (meth)acrylate, butyl (meth)acrylate, dimethylaminoethyl (meth)acrylate, isobutyl (meth)acrylate, t-butyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, and poly(ethylene glycol) methyl ether (meth)acrylate.

The content of the structural unit (b5) may be 5 to 30% by mole based on 100% by mole of the structural units constituting the fluorinated acrylate-based copolymer. Specifically, the content of the structural unit (b5) may be 5 to 25% by mole, 5 to 20% by mole, 10 to 30% by mole, 10 to 25% by mole, or 10 to 20% by mole, based on 100% by mole of the structural units constituting the fluorinated acrylate-based copolymer.

The weight average molecular weight of the fluorinated acrylate-based copolymer may be 5,000 to 15,000, preferably, 5,500 to 10,000. The weight average molecular weight may be a polymethyl methacrylate conversion value measured by gel permeation chromatography (GPC) using tetrahydrofuran as an elution solvent. Within the above molecular weight range, the adhesiveness to a substrate is more excellent, the physical and chemical properties are enhanced, and the viscosity is at a proper level.

For example, the fluorinated acrylate-based copolymer may have a weight average molecular weight of 5,000 to 15,000 and an acid value of 10 to 75 KOH mg/g.

The fluorinated acrylate-based copolymer may be prepared by mixing a radical polymerization initiator, a solvent, and monomers for obtaining the structural units, and polymerizing the mixture under a nitrogen atmosphere while stirring it slowly.

The radical polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide, lauryl peroxide, t-butyl peroxypivalate, 1,1-bis(t-butylperoxy)cyclohexane, or the like, but it is not limited thereto. The radical polymerization initiator may be used alone or in combination of two or more.

The solvent may be any conventional solvent commonly used in the preparation of a fluorinated acrylate-based copolymer and may include, for example, propylene glycol monomethyl ether acetate (PGMEA).

### Photosensitive Resin Composition

The photosensitive resin composition according to the present invention comprises an alkali-soluble resin, a photopolymerizable compound, and a photopolymerization initiator.

The alkali-soluble resin may comprise a fluorinated acrylate-based copolymer and may further comprise an additional copolymer. That is, the alkali-soluble resin may comprise two or more copolymers.

According to an embodiment, the photosensitive resin composition according to the present invention comprises copolymer A and copolymer B as an alkali-soluble resin.

### (A) Copolymer A

The copolymer A is an alkali-soluble resin for achieving developability and may play the role of a base for forming a film upon coating and a structure for forming a final pattern.

The copolymer A may comprise at least two structural units selected from the group consisting of (a1) a structural unit derived from an ethylenically unsaturated carboxylic acid, an ethylenically unsaturated carboxylic anhydride, or a combination thereof, (a2) a structural unit derived from an ethylenically unsaturated compound containing an aromatic ring, (a3) a structural unit derived from an ethylenically unsaturated compound containing an epoxy group, and (a4) a structural unit derived from an ethylenically unsaturated compound different from (a1), (a2), and (a3).

The structural unit (a1) is derived from an ethylenically unsaturated carboxylic acid, an ethylenically unsaturated carboxylic anhydride, or a combination thereof. The ethylenically unsaturated carboxylic acid and the ethylenically unsaturated carboxylic anhydride is a polymerizable unsaturated monomer containing at least one carboxyl group in the molecule. Particular examples thereof may include an unsaturated monocarboxylic acid such as (meth)acrylic acid, crotonic acid, α-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid of trivalence or more and an anhydride thereof; and a mono[(meth)acryloyloxyalkyl] ester of a polycarboxylic acid of divalence or more such as mono[2-(meth)acryloyloxyethyl] succinate, mono[2-(meth)acryloyloxyethyl] phthalate, and the like. The structural unit derived from the above-exemplified compounds may be contained in the copolymer alone or in combination of two or more.

The content of the structural unit (a1) may be 5 to 65% by mole, or 10 to 50% by mole, based on the total number of moles of the structural units constituting the copolymer A. Within the above range, it may have favorable developability.

The structural unit (a2) is derived from an ethylenically unsaturated compound containing an aromatic ring. Particular examples of the ethylenically unsaturated compound containing an aromatic ring may include phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate; styrene; styrene containing an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene containing a halogen such as fluorostyrene, chlorostyrene, bromostyrene, and iodostyrene; styrene containing an alkoxy substituent such as methoxystyrene, ethoxystyrene, and propoxystyrene; 4-hydroxystyrene, p-hydroxy-α-methylstyrene, acetylstyrene; and vinyltoluene, divinylbenzene, vinylphenol, o-vinylbenzyl methyl ether, m-vinylbenzyl methyl ether, p-vinylbenzyl methyl ether, o-vinylbenzyl glycidyl ether, m-vinylbenzyl glycidyl ether, p-vinylbenzyl glycidyl ether, and the like. The structural unit derived from the above-exemplified compounds may be contained in the copolymer alone or in combination of two or more. For polymerizability of the composition, a structural unit derived from styrene-based compounds is preferred among these examples.

The content of the structural unit (a2) may be 1 to 50% by mole, or 3 to 40% by mole, based on the total number of moles of the structural units constituting the copolymer A. Within the above range, it may be more advantageous in terms of chemical resistance.

The structural unit (a3) is derived from an ethylenically unsaturated compound containing an epoxy group. Particular examples of the ethylenically unsaturated compound containing an epoxy group may include glycidyl (meth)acrylate, 3,4-epoxy⁻butyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-t2,3-epoxypropoxy -3,5-dimethylbenzyl)acrylamide, N-(4-(2,3-epoxy propoxy)-3,5-dimethylphenylpropyl)acrylamide, 4-hydroxybutyl (meth)acrylate glycidyl ether, 4-hydroxybutyl acrylate glycidyl ether, allyl glycidyl ether, 2-methylallyl glycidyl ether, and the like. The structural unit derived from the above-exemplified compounds may be contained in the copolymer alone or in combination of two or more. At least one selected from the structural units derived from glycidyl (meth)acrylate, 3,4-epoxycyclohexyl (meth)acrylate, 4-hydroxybutyl acrylate glycidyl ether, and 4-hydroxybutyl (meth)acrylate glycidyl ether among the above is more preferable from the viewpoint of copolymerizability and enhancements in the strength of a cured film.

The content of the structural unit (a3) may be 1 to 40% by mole, or 5 to 20% by mole, based on the total number of moles of the structural units constituting the copolymer A. Within the above range, it may be more advantageous in terms of residues during the process and margins upon pre-bake.

The copolymer A may further comprise, in addition to (a1), (a2), and (a3), a structural unit derived from an ethylenically unsaturated compound different from (a1), (a2), and (a3).

Particular examples of the structural unit derived from an ethylenically unsaturated compound different from the structural units (a1) (a2), and (a3) may include an unsaturated carboxylic acid ester such as methyl (meth)acrylate, ethyl (meth)acrylate, butyl (meth)acrylate, dimethylaminoethyl (meth)acrylate, isobutyl (meth)acrylate t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethlacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, and polyethylene glycol) methyl ether (meth)acrylate; a tertiary amine containing an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, N-cyclohexylmaleimide, and the like. The structural unit derived from the above-exemplified compounds may be contained in the copolymer alone or in combination of two or more.

The content of the structural unit (a4) may be greater than 0 to 80% by mole, 30 to 70% by mole, or 30 to 50% by mole, based on the total number of moles of the structural units constituting the copolymer A. Within the above range, the storage stability of the photosensitive resin composition may be maintained, and the film retention rate may be more advantageously enhanced.

According to an embodiment, examples of the copolymer having the structural units (a1) to (a4) may include a copolymer of (meth)acrylic acid/styrene/methyl (meth)acrylate/glycidyl (meth)acrylate, a copolymer of (meth)acrylic acid/styrene/methyl (meth)acrylate/glycidyl (meth)acrylate/N-phenylmaleimide, a copolymer of (meth)acrylic acid/styrene/methyl (meth)acrylate/glycidyl (meth)acrylate/N-cyclohexylmaleimide, a copolymer of (meth)acrylic acid/styrene/n-butyl (meth)acrylate/glycidyl (meth)acrylate/N-phenylmaleimide, a copolymer of (meth)acrylic acid/styrene/glycidyl (meth)acrylate/N-phenylmaleimide, a copolymer of (meth)acrylic acid/styrene/4-hydroxybutyl acrylate glycidyl ether/N-phenylmaleimide, and the like. One, two, or more of the copolymers may be contained in the photosensitive resin composition.

The weight average molecular weight of the copolymer A may be 4,000 to 20,000 or 6,000 to 15,000. If the weight average molecular weight of the copolymer A is within the above range, the step difference by a lower pattern may be advantageously improved, and a pattern profile upon development may be favorable.

The content of the copolymer A may be 30 to 80% by weight, preferably, 35 to 65% by weight, based on the total weight of the photosensitive resin composition, exclusive of solvents. Within the above content range, a pattern profile upon development may be favorable, and such properties as film retention rate and chemical resistance may be further enhanced.

The copolymer A may be prepared by charging to a reactor a radical polymerization initiator, a solvent, and at least two of the structural units (a1), (a2), (a3), and (a4), followed by slowly stirring the mixture for polymerization under a nitrogen atmosphere.

The radical polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide, lauryl peroxide, t-butyl peroxypivalate, 1,1-bis(t-butylperoxy)cyclohexane, or the like, but it is not limited thereto. The radical polymerization initiator may be used alone or in combination of two or more.

The solvent may be any conventional solvent commonly used in the preparation of the copolymer A and may include, for example, propylene glycol monomethyl ether acetate (PGMEA).

### (B) Copolymer B

The copolymer B is a fluorinated acrylate-based copolymer, which enhances the water repellency of the photosensitive resin composition, so that it is possible to prevent the ink liquid from leaching out when it is used for the barrier ribs of a top coating for inkjet. In addition, the fluorinated acrylate-based copolymer suppresses the film aggregation phenomenon upon the coating of the photosensitive resin composition, whereby it is expected to promote the stable formation of a pattern.

The copolymer B comprises a copolymer comprising (b1) a structural unit represented by the following Formula 1a or 1b, (b2) a structural unit represented by the following Formula 2, (b3) a structural unit represented by the following Formula 3, and (b4) a structural unit derived from an ethylenically unsaturated carboxylic acid:

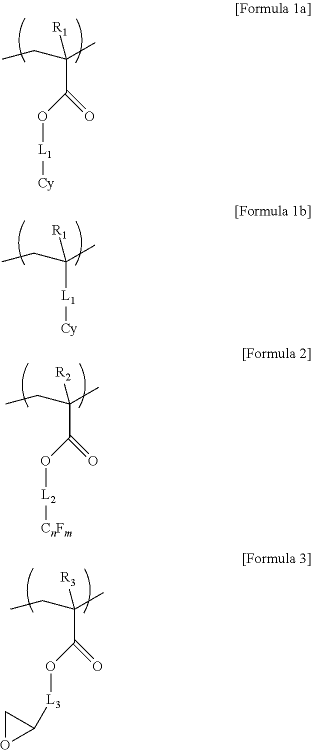

In the above formulae, R₁, R₂, and R₃ are each independently hydrogen or alkyl having 1 to 6 carbon atoms; L₁, L₂, and L₃ are each independently a single bond or a. chain having 1 to 10 carbon atoms with or without one or more heteroatoms selected from N. S, and O; Cy is an aromatic or non-aromatic hydrocarbon ring having 4 to 13 carbon atoms with or without one or more substituents; and CₙFₘ is fluoroalkyl having n carbon atoms and m fluorine atoms, wherein n is an integer of 1 to 10, m is an integer of 1 or more, and 2n−2≤m≤2n+1.

In Formulae 1a to 3, specific types of R₁, R₂, R₃, L₁, L₂, L₃, Cy, and CₙFₘ are the same as those exemplified above on the fluorinated acrylate-based copolymer.

As a specific example, in Formulae 1a and 1b, Cy may be selected from the group consisting of phenyl, cyclohexyl, and dicyclopentanyl, each having one or more substituents or not.

In addition, the constitution, characteristics, and preparation process of the copolymer B are the same as those exemplified above on the fluorinated acrylate-based copolymer.

The content of the copolymer B may be 0.1 to 10% by weight, preferably, 0.5 to 5% by weight, more preferably, 1 to 3% by weight, based on the total weight of the photosensitive resin composition, exclusive of solvents. Within the above content range, it is advantageous from the viewpoint of improvements in the surface roughness and is less likely to cause problems in compatibility in the resin composition.

### (C) Photopolymerizable Compound

The photopolymerizable compound employed in the present invention is a compound that is polymerizable by the action of a photopolymerization initiator. It may include a monofunctional or multifunctional ester compound having at least one ethylenically unsaturated group. It may preferably be a multifunctional compound having two or more functional groups from the viewpoint of chemical resistance.

The polymerizable compound may be at least one selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, a monoester of pentaerythritol tri(meth)acrylate and succinic acid, pentaerythritol tetra(meth)acrylate, dipentaerythritol penta(meth)acrylate, dipentaerythritol hexa(meth)acrylate, a monoester of dipentaerythritol penta(meth)acrylate and succinic acid, caprolactone modified dipentaerythritol hexa(meth)acrylate, pentaerythritol triacrylate-hexamethylene diisocyanate (a reaction product of pentaerythritol triacrylate and hexamethylene diisocyanate), tripentaerythritol hepta(meth)acrylate, tripentaerythritol octa(meth)acrylate, bisphenol A epoxyacrylate, and ethylene glycol monomethyl ether acrylate, but it is not limited thereto.

In addition, it may include a multifunctional urethane acrylate compound obtained by reacting a compound having a straight-chain alkylene group and an aromatic structure with two or more isocyanate groups and a compound having one or more hydroxyl groups and three, four, or five acryloyloxy groups and/or methacryloyloxy groups in the molecule, but it is not limited thereto.

Examples of the photopolymerizable compound commercially available may include a monofunctional (meth)acrylate such as Aronix M-101, M-111, and M-114 manufactured by Toagosei Co., Ltd., AKAYARAD T4-110S and T4-120S manufactured by Nippon Kayaku Co., Ltd., and V-158 and V-2311 manufactured by Osaka Yuki Kagaku Kogyo Co., Ltd.; a bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kagaku Kogyo Co., Ltd.; and a tri- and higher functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, DPH1-40H, DPC1-20, DPC1-30, DPC1-60, and DPC1-120 manufactured by Nippon Kayaku Co., Ltd., and V-295, V-300, V-360, V-OPT, V-3PA, and V-400 manufactured by Osaka Yuki Kagaku Kogyo Co., Ltd.

The photopolymerizable compounds may be used alone or in combination of two or more thereof.

The content of the photopolymerizable compound in the composition may be 10 to 200 parts by weight, 10 to 150 parts by weight, 10 to 100 parts by weight, preferably, 50 to 150 parts by weight or 90 to 130 parts by weight, relative to 100 parts by weight (on the basis of solids content) of the alkali-soluble resin (i.e., the total content of the copolymer A and the copolymer B). Within the above content range, it is possible to maintain a constant film retention rate and to obtain more excellent pattern developability and coating film characteristics.

### (D) Photopolymerization Initiator

The photopolymerization initiator employed in the present invention may serve to initiate the polymerization of monomers that can be cured by visible light, ultraviolet radiation, deep-ultraviolet radiation, or the like.

The photopolymerization initiator may be at least one selected from the group consisting of an acetophenone-based, benzophenone-based, benzoin-based, benzoyl-based, xanthone-based, triazine-based, halomethyloxadiazole-based, and rofindimer-based photopolymerization. initiators, but it is not limited thereto.

Particular examples of the photopolymerization initiator may include p-dimethylaminoacetophenone, 2-benzyl-2-(dimethylamino)-1-[4-(4-morpholinyl)phenyl]-1-butanone, 2-hydroxy-2-methyl-1 -phenyl-propan-1-one, benzyl dimethyl ketal, benzophenone, benzoin propyl ether, diethyl thioxanthone, 2,4-bis (trichloromethyl)-6-p-methoxyphenyl-s-triazine 2-trichloromethyl-5-styryl-1,3,4-oxodiale, 9-phenylacridine, 3 -methyl-5-amino-((s-triazin-2-yl)amino)-3-phenylcoumarin, 2-(o-chlorophenyl)-4,5-diphenylimidazolyl dimer, 1-phenyl- L2-propanedione-2-(o-ethoxycarbonyl)oxime, 1[4-(phenylthio)phenyl]octane-1,2-dione-2-(o-benzoyloxime), o-enzoyl-4′-(benzmercapto)benzoyl-hexyl-ketoxime, 2,4,6-trimethylphenylcarbonyl-diphenylphosphonyloxide, a hexafluorophosphoro-trialkylphenylsulfonium salt, 2-mercaptobenzimidazole, 2,2′-benzothiazolyl disulfide, and a mixture thereof, but it is not limited thereto.

As another example, the photopolymerization initiator may comprise at least one oxime-based compound.

The oxime-based compound is not particularly limited as long as it is a radical initiator comprising an oxime structure. for example, it may be an oxime ester-based compound, preferably, an oxime ester fluorene-based compound.

It is preferable to use, as the oxime-based compound, at least one oxime-based compound disclosed in Korean Laid-open Patent Publication Nos. 2004-0007700, 2005-0084149, 2008-0083650, 2008-0080208, 2007-0044062, 2007-0091110, 2007-0044753, 2009-0009991, 2009-0093933, 2010-0097658, 2011-0059525, 2011-0091742, 2011-0026467, 2011-0015683, and 2013-0124215, Korean Patent No. 10-1435652, and. International Publication Nos. 2010/10102502 and 2010/133077 from the viewpoint of high sensitivity.

The trade names thereof may be OXE-01 (BASF), OXE-02 (BASF), N-1919 (ADEKA), NCI-930 (ADEKA), NCI-831 (ADEKA), SPI-02 (Samyang EMS), SPI-03 (Samyang EMS), and the like.

The content of the photopolymerization initiator in the composition may be 0.1 to 20 parts by weight, preferably, 1 to 10 parts by weight, relative to 100 parts by weight (on the basis of solids content) of the alkali-soluble resin. Within the above content range, it is possible to achieve high sensitivity with excellent developability and coating film characteristics.

### (E) Adhesion Supplement

The photosensitive resin composition of the present invention may further comprise an adhesion supplement to enhance the adhesiveness to a substrate.

The adhesion supplement may have at least one reactive group selected from the group consisting of a carboxyl group, a (meth)acryloyl group, an isocyanate group, an amino group, a mercapto group, a vinyl group, and an epoxy group.

The kind of the adhesion supplement is not particularly limited. It may be at least one selected from the group consisting of trimethoxysilyl benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, γ-glycidoxypropyltriethoxysilane, N-phenylaminopropyltrimethoxysilane, β-(3,4-epoxycyclohexypethyltrimethoxysilane, 3-isocyanatepropyltriethoxysilane, and mixtures thereof.

Preferred is γ-glycidoxypropyltrimethoxysilane, γ-glycidoxypropyltriethoxysilane, 3-isocyanate propyltriethoxysilane, or N-phenylaminopropyltrimethoxysilane, which is capable of enhancing the film retention rate and the adhesiveness to a substrate.

The content of the adhesion supplement in the composition may be 0.001 to 10 parts by weight, preferably, 0.01 to 6 parts by weight, relative to 100 parts by weight (on the basis of solids content) of the alkali-soluble resin. Within the above content range, the adhesiveness to a substrate may be further favorable.

### (F) Surfactant

The photosensitive resin composition of the present invention, if necessary, may further comprise a surfactant in order to enhance the coatability and to prevent the generation of defects.

The kind of surfactant is not particularly limited, Preferably, it may include fluorine-based surfactants, silicone-based surfactants, non-ionic surfactants, and other surfactants. Preferably, BYK 333 from BYK among the above may be employed from the viewpoint of dispersibility.

Examples of the surfactant may include fluorine- and silicone-based surfactants such as BM-1000 and BM-1100 manufactured by BM CHEMIE Co., Ltd., Megapack F142 ID, F172, F173, F183, F-470, F-471, F-475, F-482, and F-489 manufactured by Dal Nippon Ink Chemical Kogyo Co., Ltd., Florad FC-135, FC-170 C, FC-430, and FC-431 manufactured by Sumitomo 3M Ltd., Sufron S-112, S-113, S-131, S-141, S-145, S-382, SC-101, SC-102, SC-103, SC-104. SC-105, and SC-106 manufactured by Asahi Glass Co., Ltd., Eftop EF301, 303, and 352 manufactured by Shinakida Kasei Co., Ltd., SH-28 PA, SH-190, SH-193, SZ-6032, SF-8428, DC-57, and DC-190 manufactured by Toray Silicone Co,, Ltd., DC3PA, DC7PA, SH11PA, SH21PA, 5H8400, FZ-2100, FZ-2110, FZ-2122, FZ-2222, and FZ-2233 manufactured by Dow Corning Toray Silicone Co., Ltd., TSF-4440, TSF-4300, TSF-4445, TSF-4446, TSF-4460, and TSF-4452 manufactured by GE Toshiba Silicones Co., Ltd., and BYK-333 manufactured by BYK Corporation; non-ionic surfactants such as polyoxyethylene alkyl ethers such as polyoxyethylene lauryl ether, polyoxyethylene stearyl ether, and polyoxyethylene oleyl ether; polyoxyethylene aryl ethers such as polyoxyethylene octylphenyl ether and polyoxyethylene nonylphenyl ether; and polyoxyethylene dialkyl esters such as polyoxyethylene dilaurate and polyoxyethylene distearate; and organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.), and the like. They may be used alone or in combination of two or more thereof.

The content of the surfactant in the composition may be 0.001 to 5 parts by weight, preferably, 0.01 to 2 parts by weight, relative to 100 parts by weight (on the basis of solids content) of the alkali-soluble resin. Within the above content range, the coating of the composition may be more smoothly carried out.

In addition, the photosensitive resin composition of the present invention may comprise other additives such as an antioxidant and a stabilizer as long as the physical properties thereof are not adversely affected.

### (G) Solvent

The photosensitive resin composition of the present invention may preferably be prepared as a liquid composition in which the above components are mixed with a solvent.

Any solvent known in the art, which is compatible but not reactive with the components in the photosensitive resin composition, may be used as the solvent in the preparation of the photosensitive resin composition.

Examples of such solvents include ethylene glycol monoalkyl ether acetates such as ethylene glycol monomethyl ether acetate and ethylene glycol monoethyl ether acetate; propylene glycol monoalkyl ethers such as propylene glycol monomethyl ether, propylene glycol monoethyl ether, propylene glycol monopropyl ether, and propylene glycol monobutyl ether; propylene glycol dialkyl ethers such as propylene glycol dimethyl ether, propylene glycol diethyl ether, propylene glycol dipropyl ether, and propylene glycol dibutyl ether; dipropylene glycol dialkyl ethers such as dipropylene glycol dimethyl ether; propylene glycol monoalkyl ether acetates such as propylene glycol monomethyl ether acetate, propylene glycol monoethyl ether acetate, propylene glycol monopropyl ether acetate, and propylene glycol monobutyl ether acetate; cellosolves such as ethyl cellosolve and butyl cellosolve; carbitols such as butyl carbitol lactic acid esters such as methyl lactic acid, ethyl lactic acid, n-propyl lactic acid, and isopropyl lactic acid; aliphatic carboxylic acid esters such as ethyl acetic acid, n-propyl acetic acid, isopropyl acetic acid, n-butyl acetic acid, isobutyl acetic acid, n-amyl acetic acid, isoamyl acetic acid, isopropyl propionic acid, n-butyl propionic acid, and isobutyl propionic acid; esters such as methyl 3-methoxypropionic acid, ethyl 3-methoxypropionic acid, methyl 3-ethoxypropionic acid, ethyl 3-ethoxypropionic acid, methyl pyruvic acid, and ethyl pyruvic acid; aromatic hydrocarbons such as toluene and xylene; ketones such as 2-heptanone, 3-heptanone, and 4-heptanone; amides such as N-dimethylformamide, N-methylacetamide, N,N-dimethylacetamide, and N-methylpyrrolidone; lactones such as γ-butyrolactone; and mixtures thereof, but they are not limited thereto. The solvent may be used alone or in combination of two or snore.

In the photosensitive resin composition according to the present invention, the content of the solvent is not particularly limited. The content of the solvent may be adjusted such that the solids content is 5 to 70% by weight, preferably, 10 to 55% by weight, based on the total weight of the photosensitive resin composition, from the viewpoint of coatability, stability, and the like of the composition.

### Characteristics and Application

As described above, since the photosensitive resin composition comprises a fluorinated acrylate-based copolymer to which a non-polar ring-containing unit is introduced, it has excellent water repellency even with a relatively low content of fluorine, thereby lowering the production cost as compared with the prior art. In addition, the photosensitive resin composition may prevent coating imbalance and decreases in the pattern strength that may occur when the fluorine content is high.

The photosensitive resin composition may be used to prepare a cured film for an electric device such as a display device. For example, the photosensitive resin composition may be cured at a temperature of 70° C. to I 50° C. or 80° C. to 120° C.

The cured film may be formed by a method known in the art, for example, a method in which the photosensitive resin composition is coated on a substrate and then cured. More specifically, in the curing step, the photosensitive resin composition coated on a substrate may be subjected to pre-bake at a temperature of, for example, 70° C. to 150° C. to remove solvents; then exposed to light using a photomask having a desired pattern; and subjected to development using a developer (e.g., an aqueous solution of tetramethylammonium hydroxide) to form a pattern on the coating layer. Thereafter, the patterned coating layer, if necessary, is subjected to post-bake, for example, at a temperature of 150° C. to 300° C. for 10 minutes to 5 hours to prepare a desired cured film. The exposure to light may be carried out at an exposure dose of 10 mJ/cm² to 200 mJ/cm² based on a wavelength of 365 nm in a wavelength band of 200 nm to 500 nm.

The coating of the photosensitive resin composition onto a substrate may be carried out by a spin coating method, a slit coating method, a roll coating method, a screen printing method, an applicator method, or the like, in a desired thickness of, for example, 2 μm to 25 μm. In addition, as a light source used for the exposure (irradiation), a low-pressure mercury lamp, a high-pressure mercury lamp, an extra high-pressure mercury lamp, a metal halide lamp, an argon gas laser, or the like may be used. X-rays, electronic rays, or the like may also be used, if desired, The photosensitive resin composition of the present invention is capable of forming a cured film that is excellent in terms of the thermal resistance, transparency, dielectric constant, solvent resistance, acid resistance, and alkali resistance. Therefore, the cured film of the present invention thus formed has excellent light transmittance devoid of surface roughness when it is subjected to thermal treatment or is immersed in, or conies into contact with a solvent, an acid, a base, or the like. Thus, the cured film can be effectively used as a planarization film for a thin-film transistor (TFT) substrate of a liquid crystal display or an organic EL display; barrier ribs for an organic EL display; an interlayer dielectric of a semiconductor device; a core or cladding material of an optical waveguide, or the like. Further, the present invention provides an electronic component that comprises the cured film.

In particular, since the photosensitive resin composition according to the present invention comprises a fluorinated acrylate-based copolymer, it has excellent water repellency, so that it is possible to prevent the ink liquid from leaching out when it is used for the barrier ribs of a top coating for inkjet. In addition, the photosensitive resin composition can be expected to form a stable pattern while the film aggregation phenomenon is suppressed after coating. Accordingly, the photosensitive resin composition may be used in the preparation of barrier ribs of a top coating for inkjet.

### Mode for the Invention

Hereinafter, the present invention will be described in more detail with reference to the following. examples. However, these examples are provided to illustrate the present invention, and the scope of the present invention is not limited thereto only.

The weight average molecular weight described in the following preparation example is a polymethyl methacrylate conversion value measured by gel permeation chromatography (GPC) using tetrahydrofuran as an elution solvent.

### Preparation Example 1: Copolymer B-1

A 250-ml, round-bottomed flask equipped with a refluxing condenser and a stirrer in a nitrogen atmosphere was charged with 140 g of propylene glycol methyl ether acetate (PGMEA) as a solvent, and the temperature was raised to 65° C. Charged thereto was a monomer mixture of 10% by mole of trifluoroethyl methacrylate, 50% by mole of perfluorohexyl methacrylate, 30% by mole of methacrylic acid, and 10% by mole of glycidyl methacrylate, along with 3 parts by mole of a radical polymerization initiator (V-65, Wako) and 5 parts by mole of dodecanethiol as a molecular weight controlling agent based on 100 parts by weight of the monomer mixture. Then, the polymerization was carried out for 18 hours. As a result, a copolymer having a weight average molecular weight (Mw) of 15,000 and a polydispersity (Mw/Mn) of 2.9 was obtained.

### Preparation Example 2: Copolymer B-2

A 250-ml, round-bottomed flask equipped with a refluxing condenser and a stirrer in a nitrogen atmosphere was charged with 140 g of propylene glycol methyl ether acetate (PGMEA) as a solvent, and the temperature was raised to 65° C. Charged thereto was a monomer mixture of 25% by mole of styrene, 30% by mole of trifluoroethyl methacrylate, 10% by mole of perfluorohexyl methacrylate, 20% by mole of methacrylic acid, and 15% by mole of glycidyl methacrylate, along with 3 parts by mole of a radical polymerization initiator (V-65, Wako) and 5 parts by mole of dodecanethiol as a molecular weight controlling agent based on 100 parts by weight of the monomer mixture. Then, the polymerization was carried out for 18 hours. As a result, a copolymer having a weight average molecular weight (Mw) of 10,000 and a polydispersity (Mw/Mn) of 2.9 was obtained.

### Preparation Example 3: Copolymer B-3

A 250-ml, round-bottomed flask equipped with a refluxing condenser and a stirrer in a nitrogen atmosphere was charged with 140 g of propylene glycol methyl ether acetate (PG MEA) as a solvent, and the temperature was raised to 65° C. Charged thereto was a monomer mixture of 25% by mole of styrene, 25% by mole of trifluoroethyl methacrylate, 15% by mole of perfluorohexyl methacrylate, 20% by mole of methacrylic acid, and 15% by mole of glycidyl methacrylate, along with 3 parts by mole of a radical polymerization initiator (V-65, Wako) and 5 parts by mole of dodecanethiol as a molecular weight controlling agent based on 100 parts by weight of the monomer mixture. Then, the polymerization was carried out for 18 hours. As a result, a copolymer having a weight average molecular weight (Mw) of 9,200 and a polydispersity (Mw/Mn) of 2.56 was obtained.

### Preparation Example 4: Copolymer B-4

A 250-ml, round-bottomed flask equipped with a refluxing condenser and a stirrer in a nitrogen atmosphere was charged with 140 g of propylene glycol methyl ether acetate (PGMEA) as a solvent, and the temperature was raised to 65° C. Charged thereto was a monomer mixture of 25% by mole of dicyclopentanyl methacrylate, 25% by mole of trifluoroethyl methacrylate, 15% by mole of perfluorohexyl methacrylate, 20% by mole of methacrylic acid, and 15% by mole of glycidyl methacrylate, along with 3 parts by mole of a radical polymerization initiator (V-65, Wako) and 5 parts by mole of dodecanethiol as a molecular weight controlling agent based on 100 parts by weight of the monomer mixture. Then, the polymerization was carried out for 18 hours. As a result, a copolymer having a weight average molecular weight (Mw) of 8,600 and a polydispersity (Mw/Mn) of 3.0 was obtained.

### Preparation Example 5: Copolymer B-5

A 250-ml, round-bottomed flask equipped with a refluxing condenser and a stirrer in a nitrogen atmosphere was charged with 140 g of propylene glycol methyl ether acetate (PGMEA) as a solvent, and the temperature was raised to 65° C. Charged thereto was a monomer mixture of 30% by mole of dicyclopentanyl methacrylate, 25% by mole of trifluoroethyl methacrylate, 10% by mole of perfluorohexyl methacrylate, 20% by mole of methacrylic acid, and 15% by mole of glycidyl methacrylate, along with 3 parts by mole of a radical polymerization initiator (V-65, Wako) and 2 parts by mole of dodecanethiol as a molecular weight controlling agent based on 100 parts by weight of the monomer mixture. Then, the polymerization was carried out for 18 hours. As a result, a copolymer having a weight average molecular weight (Mw) of 8,400 and a polydispersity (Mw/Mn) of 2.9 was obtained,

### Preparation Example 6: Copolymer B-6

A 250-ml, round-bottomed flask equipped with a refluxing condenser and a stirrer in a nitrogen atmosphere was charged with 140 g of propylene glycol methyl ether acetate (PGMEA) as a solvent, and the temperature was raised to 65° C. Charged thereto was a monomer mixture of 20% by mole of cyclohexyl methacrylate, 20% by mole of trifluoroethyl methacrylate, 25% by mole of perfluorohexyl methacrylate, 20% by mole of methacrylic acid, and 15% by mole of glycidyl methacrylate, along with 3 parts by mole of a radical polymerization initiator (V-65, Wako) and 2 parts by mole of dodecanethiol as a molecular weight controlling agent based on 100 parts by weight of the monomer mixture. Then, the polymerization was carried out for 18 hours, As a result, a copolymer having a weight average molecular weight (Mw) of 7,400 and a polydispersity (Mw/Mn) of 2.2 was obtained.

### Preparation Example 7: Copolymer B-7

A 250-ml, round-bottomed flask equipped with a refluxing condenser and a stirrer in a nitrogen atmosphere was charged with 140 g of propylene glycol methyl ether acetate (PGMEA) as a solvent, and the temperature was raised to 65° C. Charged thereto was a monomer mixture of 30% by mole of cyclohexyl methacrylate, 25% by mole of trifluoroethyl methacrylate, 10% by mole of perfluorohexyl methacrylate, 20% by mole of methacrylic acid, and 15% by mole of glycidyl methacrylate, along with 3 parts by mole of a radical polymerization initiator (V-65, Wako) and 2 parts by mole of dodecanethiol as a molecular weight controlling agent based on 100 parts by weight of the monomer mixture. Then, the polymerization was carried out for 18 hours. As a result, a copolymer having a weight average molecular weight (Mw) of 8,400 and a polydispersity (Mw/Mn) of 2.8 was obtained.

TABLE 1

| | Copolymerization monomer, % by mole | | | | | |
|---|---|---|---|---|---|---|
| | (b1) | (b2) | | (b3) | (b4) | Mw |
| Copolymer B-1 | — | TFEMA | PFHMA | GMA | MAA | 15,000 |
| | — | 10 | 50 | 10 | 30 | |
| Copolymer B-2 | Sty | TFEMA | PFHMA | GMA | MAA | 10,000 |
| | 25 | 30 | 10 | 15 | 20 | |
| Copolymer B-3 | Sty | TFEMA | PFHMA | GMA | MAA | 9,200 |
| | 25 | 25 | 15 | 15 | 20 | |
| Copolymer B-4 | DCPMA | TFEMA | PFHMA | GMA | MAA | 8,600 |
| | 25 | 25 | 15 | 15 | 20 | |
| Copolymer B-5 | DCPMA | TFEMA | PFHMA | GMA | MAA | 8,400 |
| | 30 | 25 | 10 | 15 | 20 | |
| Copolymer B-6 | CHMA | TFEMA | PFHMA | GMA | MAA | 7,400 |
| | 20 | 20 | 25 | 15 | 20 | |
| Copolymer B-7 | CHMA | TFEMA | PFHMA | GMA | MAA | 8,400 |
| | 30 | 25 | 10 | 15 | 20 | |

CHMA: cyclohexyl methacrylate,
TFEMA: trifluoroethyl methacrylate,
PFHMA: perfluorohexyl methacrylate,
DCPMA: dicyclopentanyl methacrylate,
MAA: methacrylic acid,
GMA: glycidyl methacrylate,
Sty: styrene

### Examples 1 to 6 and Comparative Example 1: Preparation of Photosensitive Resin Compositions

As shown in Tables 2 and 3 below, 48 parts by weight of a copolymer (A), parts by weight of the copolymer (any of B-1 to B-7), 50 parts by weight of a photopolymerizable compound (C), 0.6 parts by weight of a photopolymerization initiator (D), 2.8 parts by weight of an adhesion supplement (E), and 0.15 parts by weight of a surfactant (F) were blended. Added thereto was 100 parts by weight of a solvent (H) such that the solids content was 19% by weight. Then, they were mixed using a shaker for 3 hours to prepare a liquid photosensitive resin composition.

TABLE 2

| | Composition (component and part by weight) | | | | | | | | | | | | | |
|---|---|---|---|---|---|---|---|---|---|---|---|---|---|---|
| | Copolymer | | Copolymer | | Photopolymerizable | | Photopolymerization | | Adhesion | | | | | |
| | A | | B | | compound | | initiator | | supplement | | Surfactant | | Solvent | |
| C. Ex. 1 | A | 48 | B-1 | 2 | C | 50 | D | 0.6 | E | 2.8 | F | 0.15 | H | 100 |
| Ex. 1 | A | 48 | B-2 | 2 | C | 50 | D | 0.6 | E | 2.8 | F | 0.15 | H | 100 |
| Ex. 2 | A | 48 | B-3 | 2 | C | 50 | D | 0.6 | E | 2.8 | F | 0.15 | H | 100 |
| Ex. 3 | A | 48 | B-4 | 2 | C | 50 | D | 0.6 | E | 2.8 | F | 0.15 | H | 100 |
| Ex. 4 | A | 48 | B-5 | 2 | C | 50 | D | 0.6 | E | 2.8 | F | 0.15 | H | 100 |
| Ex. 5 | A | 48 | B-6 | 2 | C | 50 | D | 0.6 | E | 2.8 | F | 0.15 | H | 100 |
| Ex. 6 | A | 48 | B-7 | 2 | C | 50 | D | 0.6 | E | 2.8 | F | 0.15 | H | 100 |

* In the components other than the solvent, the solids content is indicated in part by weight.

TABLE 3

| | Component/trade name (manufacturer) |
|---|---|
| Copolymer (A) | RPR-4137 (Miwon) |
| Photopolymerizable | Dipentaerythritol hexaacrylate/DPHA |
| compound (C) | (Nippon Kayaku) |
| Photopolymerization | Mixture of T-Y (Trony) and SPI 02 |
| initiator (D) | (Samyang) |
| Adhesion supplement | Mixture of mGSCA-001 (DKSH) and |
| (E) | GHP-03HHP (Miwon) |
| Surfactant (F) | F-563 (Sanyo Finetech) |
| Solvent (H) | Propylene glycol monomethyl ether |
| | acetate/PGMEA (Chemtronics) |

### Test Example

The photosensitive resin compositions obtained in the Examples and Comparative Examples were each coated on a glass substrate using a spin coater and pre-baked at 100° C. for 60 seconds to form a coated film. A mask having a line pattern capable of 100% exposure was placed on the coated film thus formed in an area of 10 cm by 10 cm such that the gap with the substrate was maintained at 25 μm. Thereafter, the film was exposed to light at an exposure dose of 30 mJ/cm² based on a wavelength of 365 nm for a certain time period using an aligner (model name: MA6) that emits light having a wavelength of 200 nm to 450 nm. The exposed film was developed with an aqueous solution of 2.38% by weight of tetramethylammonium hydroxide (TMAH) at 23° C. until the unexposed portion was completely washed out. The patterned film thus formed was post-baked in an oven at 180° C. for 20 minutes to obtain a cured film sample having a final thickness of 2.5 (+0.2) μm.

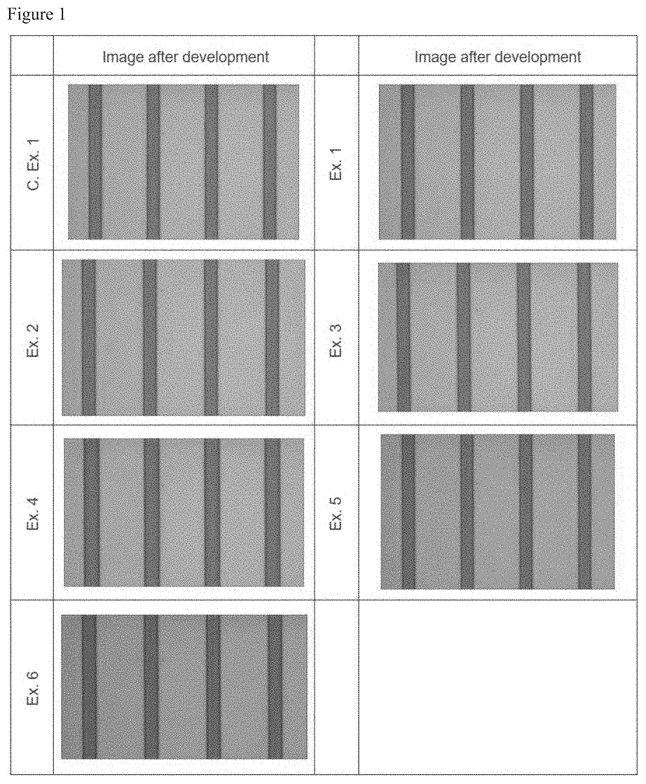

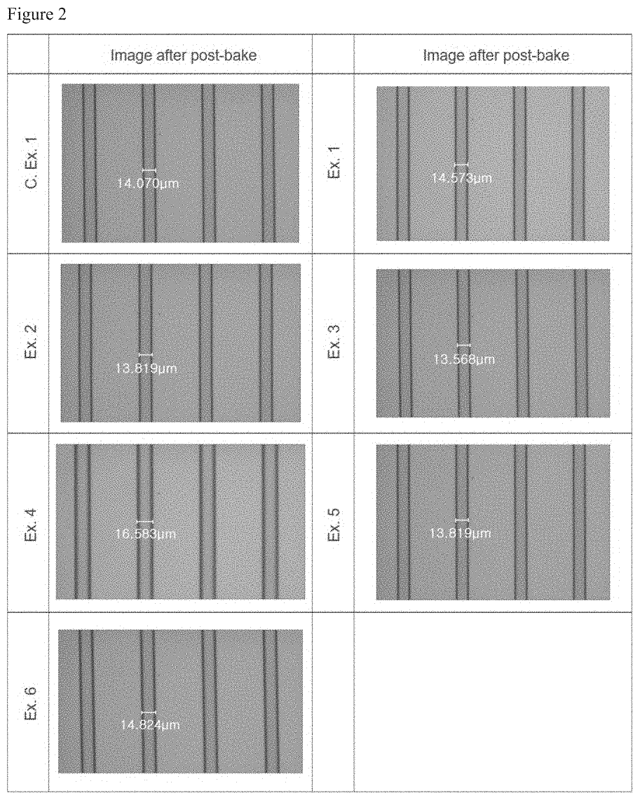

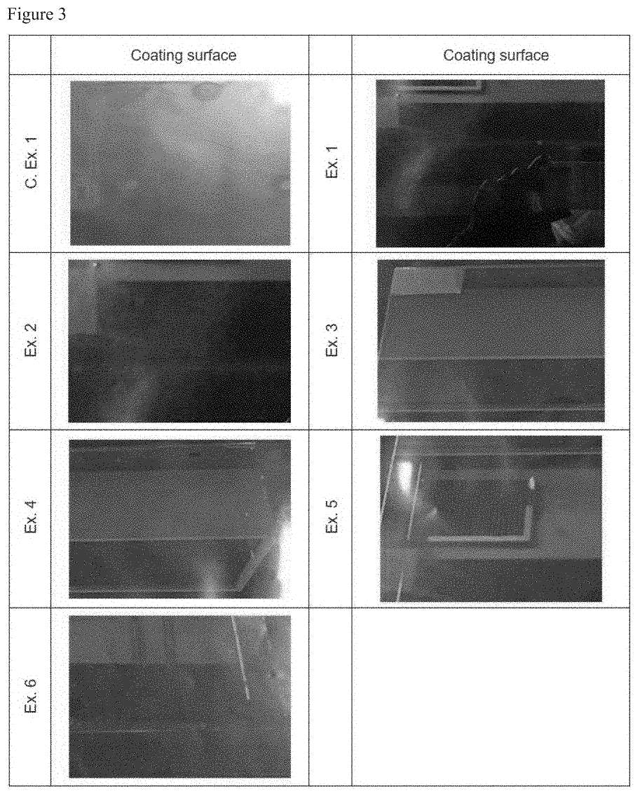

FIG. 1 shows images of the compositions of Comparative Example 1 and Examples 1 to 6 after development. FIG. 2 shows images of the compositions of Comparative Example 1 and Examples 1 to 6 after post-bake. FIG. 3 shows images of the surface of the film formed from the compositions of Comparative Example 1 and Examples 1 to 6 after pre-bake.

(1) Measurement of Contact Angle

A drop of deionized water was dropped on the surface of the cured film sample. After 5 seconds, the contact angle was measured three times with a contact angle measuring device (DM300, Kyowa Interface Science), and an average value was obtained. In addition, the contact angle of the cured film sample was measured in the same manner except that glycerol and diiodomethane were each used.

(2) Measurement of Surface Energy

The surface energy was calculated by an indirect calculation method (acid/base method—Lewis acid/base with the geometric combining rule) using the contact angles of the cured film sample measured with the three fluids (deionized water, glycerol, and diiodomethane).

(3) Measurement of Film Thickness

In the preparation process of the cured film sample, the initial film thickness before development, the film thickness after development, and the film thickness after post-bake were measured using a film thickness measuring device (SNU 3D) profiler, SNU). The film retention rate (%) was calculated according to the following equations.

Film retention rate after development (%)=(film thickness after development/initial film thickness)×100

Film retention rate after post-bake (%)=(film thickness after post-bake/initial film thickness)×100

(4) Measurement of optical CD (total CD)

The pattern of the cured film sample was observed at a magnification of 50 times using an optical microscope (STM6-LM, OLYMPUS) (see FIG. 2). The CD (critical dimension) of the pattern was measured from the optical microscope image.

(5) Evaluation of Lithography Performance

In the preparation process of the cured film sample, the state of the pattern after development was observed (see FIG. 1). If the pattern was not peeled off as attached well, it was evaluated as pass.

(6) Coating Roughness

In the preparation process of the cured film sample, the roughness of the surface of the film after post-bake was visually observed (see FIG. 3). If the surface was smooth, it was evaluated as good; otherwise, it was evaluated as poor.

(7) Measurement of Hardness The hardness of the cured film sample was measured using a surface hardness measuring instrument (Fischerscope HM2000 XYP, Fischer) (hardness measurement conditions: 100 mN, D1). The hardness was measured 5 times in total, and an average value was obtained.

TABLE 4

| | | | | | | Surface |
|---|---|---|---|---|---|---|
| | | contact angle (°) | | | | energy |
| Copolymer | Fluid | First | Second | Third | Avg. | (N/m) |
| C. Ex. 1 | Deionized water | 80.25 | 80.51 | 81.09 | 80.62 | 14.59 |
| | Glycerol | 88.39 | 93.40 | 95.52 | 92.44 | |
| | Diiodomethane | 64.77 | 63.64 | 63.26 | 63.89 | |
| Ex. 1 | Deionized water | 81.68 | 81.32 | 81.65 | 81.55 | 22.00 |
| | Glycerol | 94.48 | 94.62 | 94.48 | 94.53 | |
| | Diiodomethane | 76.50 | 76.70 | 75.62 | 76.27 | |
| Ex. 2 | Deionized water | 81.30 | 80.11 | 81.41 | 80.94 | 7.29 |
| | Glycerol | 99.43 | 96.57 | 98.01 | 98.00 | |
| | Diiodomethane | 66.07 | 66.25 | 66.20 | 66.17 | |
| Ex. 3 | Deionized water | 81.13 | 80.03 | 80.41 | 80.52 | 14.59 |
| | Glycerol | 86.88 | 89.97 | 97.94 | 91.60 | |
| | Diiodomethane | 68.07 | 69.11 | 68.01 | 68.40 | |
| Ex. 4 | Deionized water | 81.12 | 79.91 | 81.22 | 80.75 | 27.45 |
| | Glycerol | 80.79 | 80.98 | 81.08 | 80.95 | |
| | Diiodomethane | 61.14 | 61.52 | 62.13 | 61.60 | |
| Ex. 5 | Deionized water | 91.48 | 94.48 | 93.17 | 93.04 | 24.96 |
| | Glycerol | 95.73 | 92.54 | 93.29 | 93.85 | |
| | Diiodomethane | 74.79 | 73.43 | 72.62 | 73.61 | |
| Ex. 6 | Deionized water | 81.36 | 81.70 | 81.24 | 81.43 | 31.47 |
| | Glycerol | 86.08 | 88.96 | 87.61 | 87.55 | |
| | Diiodomethane | 62.82 | 61.80 | 62.67 | 62.43 | |

TABLE 5

| | | C. Ex. 1 | Ex. 1 | Ex. 2 | Ex. 3 | Ex. 4 | Ex. 5 | Ex. 6 |
|---|---|---|---|---|---|---|---|---|
| Initial thickness (Å) | | 31495 | 31868 | 31574 | 31531 | 32201 | 31673 | 32079 |
| Thickness after development (Å) | | 24345 | 24242 | 23974 | 23849 | 23880 | 23497 | 24070 |
| Film retention rate after development (%) | | 77.0% | 76.0% | 76.0% | 76.0% | 74.0% | 74.0% | 75.0% |
| Optical CD (μm) | | 14.07 | 14.57 | 13.81 | 13.56 | 16.58 | 13.81 | 14.82 |
| Thickness after post-bake (Å) | | 22319 | 21295 | 21388 | 21045 | 21417 | 20916 | 21407 |
| Film retention rate after post-bake (%) | | 70.9% | 66.8% | 67.7% | 66.7% | 66.5% | 66.0% | 66.7% |
| Lithography performance | | Pass | Pass | Pass | Pass | Pass | Pass | Pass |
| Coating film roughness | | Poor | Good | Good | Good | Good | Good | Good |
| Hardness | First | 0.591 | 0.284 | 0.231 | 0.244 | 0.248 | 0.253 | 0.261 |
| (μm) | Second | 0.529 | 0.262 | 0.241 | 0.246 | 0.254 | 0.241 | 0.281 |
| 100 mN/D1 | Third | 0.605 | 0.229 | 0.262 | 0.264 | 0.238 | 0.251 | 0.233 |
| | Fourth | 0.589 | 0.239 | 0.254 | 0.265 | 0.248 | 0.255 | 0.254 |
| | Fifth | 0.641 | 0.249 | 0.244 | 0.253 | 0.263 | 0.268 | 0.255 |
| | Avg. | 0.591 | 0.253 | 0.246 | 0.254 | 0.250 | 0.254 | 0.257 |

As shown in Tables 4 and 5, the compositions of Examples 1 to 6 maintained surface energy values with excellent water repellency even though the fluorine content was lower than that of the composition of Comparative Example 1. In addition, the compositions of Examples 1 to 6 showed good pattern formation and hardness. In particular, they were remarkably excellent in surface uniformity as compared with the composition of Comparative Example 1 (see FIGS. 1, 2, and 3). Accordingly, the compositions of Examples 1 to 6 are expected to be used to prepare barrier ribs of a top coating for inkjet while preventing leaching out of the ink liquid and forming a stable pattern.

1. A fluorinated acrylate-based copolymer comprising:
(b1) a structural unit represented by the following Formula 1a or 1b.
(b2) a structural unit represented by the following Formula 2,
(b3) a structural unit represented by the following Formula 3, and
(b4) a structural unit derived from an ethylenically unsaturated carboxylic acid: 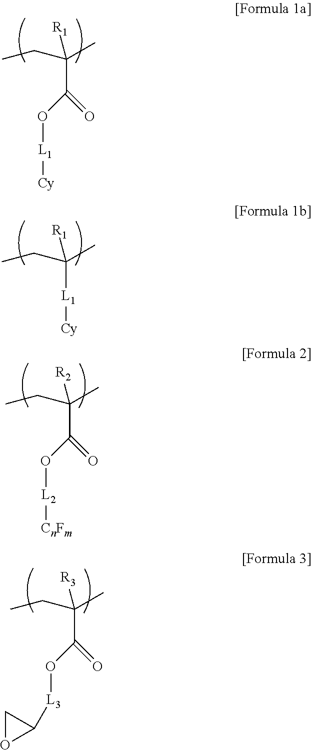
in the above formulae,
R₁, R₂, and R₃ are each independently hydrogen or alkyl having 1 to 6 carbon atoms;
L₁, L₂, and L₃ are each independently a single bond or a chain having 1 to 10 carbon atoms with or without one or more heteroatoms selected from N, S, and
Cy is an aromatic or non-aromatic hydrocarbon ring having 4 to 13 carbon atoms with or without one or more substituents; and
CₙFₘ is fluoroalkyl having n carbon atoms and m fluorine atoms, wherein n is an integer of 1 to 10, m is an integer of 1 or more, and 2n−2≤m≤2n+1.

2. The fluorinated acrylate-based copolymer of claim 1, wherein the content of the structural unit (b1) is 10 to 40% by mole based on 100% by mole of the structural units constituting the fluorinated acrylate-based copolymer.

3. The fluorinated acrylate-based copolymer of claim 1, wherein the content of the structural unit (b2) is 10 to 50% by mole based on 100% by mole of the structural units constituting the fluorinated acrylate-based copolymer.

4. The fluorinated acrylate-based copolymer of claim 1, wherein in Formulae 1a and 1b, try is selected from the group consisting of phenyl, cyclohexyl, and dicyclopentanyl, each having one or more substituents or not.

5. The fluorinated acrylate-based copolymer of claim 1, which further comprises a structural unit (b5) derived from an ethylenically unsaturated compound different from the structural units (b1) to (b4).

6. The fluorinated acrylate-based copolymer of claim 5, wherein the ethylenically unsaturated compound comprises at least one ethylenically unsaturated carboxylic acid ester-based compound.

7. The fluorinated acrylate-based copolymer of claim 1, which has a weight average molecular weight of 5,000 to 15,000 and an acid value of 10 to 75 KOH mg/g.

8. A photosensitive resin composition, which comprises an alkali-soluble resin, a photopolymerizable compound, and a photopolymerization initiator,
wherein the alkali-soluble resin comprises a copolymer comprising (b1) a structural unit represented by the following Formula 1a or 1b, (b2) a structural unit represented by the following Formula 2, (b3) a structural unit represented by the following Formula 3, and (b4) a structural unit derived from an ethylenically unsaturated carboxylic acid: 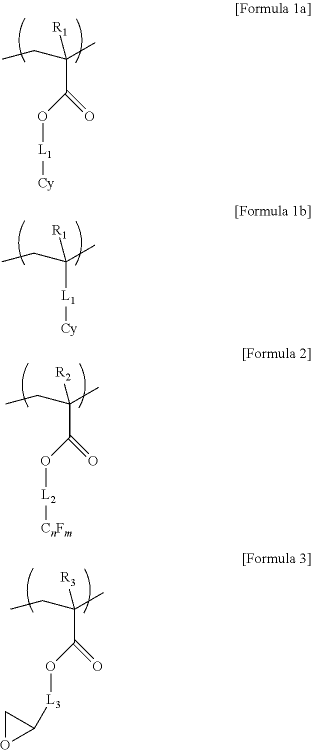
in the above formulae,
R₁, R₂, and R₃ are each independently hydrogen or alkyl having 1 to 6 carbon atoms;
L₁, L₂, and L₃ are each independently a single bond or a chain having 1 to 10 carbon atoms with or without one or more heteroatoms selected from N, S, and O.
Cy is an aromatic or non-aromatic hydrocarbon ring having 4 to 13 carbon atoms with or without one or more substituents; and
CₙFₘ is fluoroatkyl having n carbon atoms and m fluorine atoms, wherein n is an integer of 1 to 10, m is an integer of 1 or more, and 2n−2≤m≤2n+1.

9. The photosensitive resin composition of claim 8, wherein the alkali-soluble resin further comprises a copolymer comprising at least two structural units selected from the group consisting of (a1) a structural unit derived from an ethylenically unsaturated carboxylic acid, an ethylenically unsaturated carboxylic anhydride, or a combination thereof, (a2) a structural unit derived from an ethylenically unsaturated compound containing an aromatic ring, (a3) a structural unit derived from an ethylenically unsaturated compound containing an epoxy group, and (a4) a structural unit derived from an ethylenically unsaturated compound different from (a1), (a2), and (a3).

10. The photosensitive resin composition of claim 8, which further comprises an adhesion supplement and a surfactant.

11. The photosensitive resin composition of claim 8, which is cured at a temperature of 70° C. to 150° C.
